(19) United States
(12) Patent Application Publication
(10) Pub. No.: US 2010/0269888 A1
(43) Pub. Date: Oct. 28, 2010

(54) System for mounting and selectable adjustment of angle of elevation of groups of PV panels

(76) Inventor: Robert G. Johnston, JR., Coconut Cteek, FL (US)

Correspondence Address: MELVIN K. SILVERMAN AND ASSOCS PC, 500 WEST CYPRESS CREEK ROAD, SUITE 350, FT. LAUDERDALE, FL, 33309, US

(21) Appl. No.: 12/386,995

(22) Filed: Apr. 27, 2009

(51) Int. Cl. H01L 31/042; F16M 11/04

(52) U.S. Cl. 136/251; 248/176.3

(57) ABSTRACT

A system for the selectable adjustment of an angle of elevation of groups of PV panels or panel arrays, relative to a roof to which the panels are attached, includes a platform, upon or thru the roof. The platform including horizontally secured rails. Also included are a parallel series of lower couplings, each member of the series provided upon the rails, and having a transverse distance between them sufficient to accommodate a PV panel array. Each of the couplings are provided with integral extensions or tabs, each having an aperture within a portion not in engagement with the platform. The system also includes linear support members secured to undersides of the panel arrays to be selectably elevated, each of the support members substantially co-planar with the rails of the parallel series of lower couplings. Struts of fixed lengths are selectably provided between alternates of the lower couplings within each of the series of couplings, in which alternate couplings, not associated with the struts, are rotationally or pivotally secured by extension tabs of each coupling and selectably secured to couplings upon the linear support members of the panel arrays. Also provided are equal length strut pairs of selectable lengths, each strut having an aperture at each end, detachably securable between corresponding lower and upper couplings of each of the series pairs of couplings between the rotational couplings. Selection of a pair of corresponding equal length struts, related to coupling pairs upon the parallel series of couplings and rails, effects an angle of elevation of a PV panel array as a function of the length of the co-equal lengths of the struts within the parallel series of couplings and rails.

### TECHNICAL FIELD

The present invention relates generally to constructional methods for PV panel arrays, mounting hardware therefore and an improved system to effect selectable adjustment of angles of elevation of groups of PV panels relative to roofs upon which the panels are employed.

### BACKGROUND OF THE INVENTION

As used herein, the term “PV panel” or “PV array” identify photovoltaic power generating units in the form of an integrated structure comprising a plurality of electrically interconnected photovoltaic cells and means for supporting and protecting the cells. The term “PV panel group” or the like identifies the structure comprising two or more PV modules or panels that are mechanically ganged together and are electronically interconnected to form a unitary power source.

In the prior art, a variety of systems and methods have, from time-to-time, been used to effect the mounting of PV modules, arrays and associated components of electric power or PV power generating systems onto the roofs of buildings. However, the prior art, as set forth below, does not teach a mechanically simply or time and cost-effective method for selectable adjustment of the angle of elevation of such groups or assembles of PV panels after mounting to the roof. Such adjustment of the angle of elevation, relative to the plane of a roof is frequently necessitated for any number of reasons inclusive of standard maintenance of the roof, protection of the PV module groups in the event of a storm condition, and optimizing the quantity of energy received from the sun, as a function of both geographic latitude of the installation and particular time of the year.

As is known, the market for solar electric power generating systems that can operate in conjunction with existing grid electricity supplies and that can be safely and simply installed on roof tops of business, factories, schools, commercial establishments and the like, is growing rapidly in this country and abroad, particularly as a cost per watt for affordable PV units has dropped in recent years and the need for improving the nation's power grid has become a national priority. Notwithstanding the remarkable potential for such use of solar energy, certain practical problems nonetheless subsist. For example, care must be taken to ensure that PV systems are installed with due regard to environmental factors such as wind loading, mechanical loading, environmental stresses, and structural integrity, notably by minimizing the use of mechanical fasteners that penetrate the building, or doing so safely.

While the prior art teaches various strategies for the installation and roof support of a solar panel or systems thereof, relatively little prior art has sufficiently addressed the issue of optimizing the angle of elevation of a PV panel group and the need to be able to quickly and cost-effectively change this angle responsive to various factors as above set forth. Representative prior art, as is best known to the within inventor, is thus reflected in U.S. Pat. No. 5,603,187 (1997) to Merrin et al, entitled Water Type System for Mounting Equipment on Roof; U.S. Pat. No. 6,046,399 (2000) to Kapner, entitled Roofing Panels With Integral Brackets For Accepting Incline Solar Panel; and U.S. Pat. No. 7,435,897 (2008) to Russell, entitled Apparatus And Method For Mounting PV Power Generating Systems On Buildings.

The prior art, as above set forth, also fails to address other important issues in regard to the mounting of PV power arrays on building roofs, these including such systems that can be readily assembled and, if needed, disassembled, upon a building roof without requirement for use with special purpose tools and in economical fashion. The prior art also fails to address the need or desirability for PV panel array systems having sufficient elevation to permit necessary clearance between the roof and the array as not to interfere with small projections, such as vents and the like, through the roof surface, this to allow for the optimum use of the surface area of the roof so that more panels may be employed in a given area, this resulting in higher wattage yields per square foot of the system. The prior art also does not address the need to optimize support of the considerable loads associated with a large PV panel arrays using the bar joists or other load bearing beams of the building, nor does it considered means for optimizing necessary roof penetration in order to effect essential communication with load-bearing beams in a manner that will not result in a breach of a manufacturer's warranty of the roof system.

The prior art has also not considered the substantial safety risks associated with wiring of PV systems and the high risk posed to maintenance people by such wiring which is not optimally secured or positioned, particularly in conditions of water and moisture which are common upon roofs or buildings. The prior art also has not considered designs of PV roof arrays that would not interfere with normal roof installation and repair functions nor has it considered designs of solar panel arrays which would provide for walkways of sufficient width to permit ease of access thereto for purposes of servicing and repair of the arrays.

The instant invention address the above long-felt needs for such a method and system for the selectably adjustment of angles of elevation of groups of PV panels or arrays in a safe, time and cost-effective system.

### SUMMARY OF THE INVENTION

A system for the selectable adjustment of an angle of elevation of groups of PV panels or panel arrays, relative to a roof to which said panels are attached, includes (a) a platform, upon or extending thru said roof, of sufficient strength and stability to support PV panels or a PV panel array, said platform including horizontally secured rails; (b) a parallel series of lower couplings, each member of said series provided upon said rails, and having a transverse distance therebetween sufficient to accommodate a PV panel array of a weight to be supported, each of said couplings are provided with integral extensions or tabs, each having an aperture within a portion thereof not in engagement with said platform; (c) linear support members secured to undersides of said panel arrays to be selectably elevated, each of said support members substantially co-planar with said rails of said parallel series of lower couplings; (d) struts of fixed lengths selectably provided between alternates of said lower couplings within each of said series of couplings, in which alternate couplings, not associated with said struts, are rotationally or pivotally secured by extension tabs of each coupling and selectably secured to extensions of couplings upon said linear support members of said panel arrays; and (e) equal length strut pairs of selectable lengths, each strut having an aperture at each end thereof, detachably securable between corresponding lower and upper couplings of each of said series pairs thereof, between said rotational couplings. Selection of a pair of corresponding equal length struts, related to coupling pairs upon said parallel series of couplings and rails, will effect an angle of elevation of a PV panel array as a function of the length of the co-equal lengths of said struts within the parallel series of couplings and rails.

It is an object of the invention to provide a new and improved method and system for the suspension of PV module groups to a new or existing building roof in a manner to accomplish the selectable adjustment of the angle of elevation thereof relative to the roof responsive to external conditions of roof maintenance, storm or high wind conditions, geographic latitude of the PV installation, and angle of elevation for optimum receipt of solar energy at a particular time of year at the given latitude.

It is another object to provide a system for the suspension of PV modules above concrete and other flat roofs typical of commercial buildings, or of less than ten degrees, that is economical, and requires no special tools for installation.

It is a yet further object to provide a PV panel and panel system structure that promotes the structural and functional independence of the PV system through a structure which is elevated thus allowing for a greater clearance between the roof and the PV array than is known in the art.

It is another object of the invention to provide a PV structure elevation system of the above type that will furnish greater clearance of small projections, such as vents, through the roof surface and, thus, by the spanning of such projections, allowing for the installation of more panels resulting in higher wattage yields per square foot of a system.

It is a further object to provide a non-corrosive, preferably entirely aluminum structure secured directly upon the roof deck or to its structural components of the building of the roof deck, thusly providing a highly stable platform for PV panels and panel groups.

It is a yet further object to provide a method and system of the above type which enables increased structural loading of the roof and building and additionally facilitates servicing of the roof proper, as needed.

It is another object to provide an improvement over prior art ballasted systems which typically are not capable of withstanding higher speed winds and adverse weather conditions which might result in damage to the PV array and/or roof system.

It is a still further object to provide a system of the above type which may be readily installed.

It is a further object to provide an invention of a type which is useful upon all low slope ROOF systems including BUR, modified Bitumen, PVC, TPO, EPDM, polyurethane foam, liquid and other roof systems.

It is a yet further object to provide a system of the above type in which all loads that are transferred to the structural components, require fewer roof penetrations, allow for standard manufacture and roof penetration detailing (see FIG. 16 below) and eliminate what would in the prior art approach to the above problems result in breach of the manufacture warranty of the roof system.

It is a further object to provide an invention of a type which is useful upon all low slope groove systems including BUR, modified Bitumen, PVC, TPO, EPDM, polyurethane foam, Alsan liquid, Pithch, and other roof systems.

It is a still further object to provide a system of the above type in which the profile of the horizontal supports thereof will facilitate collection and safe positioning of all wiring harnessing associated with the PV array system through the location of such wiring at a significantly higher level than other panel mounting strategies known in the art.

It is another object to provide a system of the above type which is entirely module thus permitting a system designer to permit the systems to be assembled and disassembled as may be needed to accommodate roof or mechanical equipment installations and/or repairs of the roof or roofing system.

It is a further object of the invention to provide an improved system of the above type that provides for walkways between solar panel for ease of access for purposes of servicing and repair.

It is a yet further object to provide a system of the above type which includes suspension system of enhanced stability over those heretofore known in the art.

The above and yet other objects and advantages of the present invention will become apparent from the hereinafter set forth Brief Description of the Drawings, Detailed Description of the Invention and Claims appended herewith.

### BRIEF DESCRIPTION OF THE DRAWINGS

FIG. 1 is a perspective view showing the present system prior to the installation of the elevation determining struts thereof.

FIG. 2 is a perspective view, similar to that of FIG. 1, in which a selected elevation determining strut is installed.

FIG. 3 is a schematic exploded view of the system of FIG. 2.

FIG. 4 is a system view showing the installation of multiple panel groups upon a roof using the present inventive method and system.

FIG. 5 is a view, similar to FIG. 2, however in which no elevation determining strut is employed.

FIG. 6 is a system view showing the solar panel groups rotated to a 90-degree position after removal of the elevation determining strut.

FIG. 7 is a sequence of six vertical schematic views showing the range of angles between PV panel groups and roof that may be accomplished using the present inventive system, the same ranging from 90 degrees in FIG. 7A to zero degrees, that is, co-parallel to the roof, in FIG. 7F. A range of intermediate position therebetween is shown in FIGS. 7B to 7E.

FIG. 8A is an exploded view showing a portion of elevation link or strut together with associated washers, a clevis pin and hitch pin for securement of the clevis pin to the strut.

FIG. 8B is an enlarged view showing the appearance of the hitch pin when fully secured into the clevis pin.

FIG. 9 is an operational installation view showing insertion of I-beams into the uppermost hardware of the support platform as well as truss-like weight bearing beams situated beneath the roof thereof.

FIG. 9A is an enlarged view of the lower portion of the system supporting I-beam as secured to the uppermost portion of the system platform.

FIG. 10 is a further operational installation view showing the attachments of lower couplings at the top of PV panel support I-beams.

FIG. 11 is a further installation view showing attachment of PV panels.

FIG. 12A is a composite view showing the securement of the present platform to a weight-bearing beam or truss beneath the roof upon which the PV panel groups are to be installed.

FIG. 12B is a view showing the manner of securement of a platform upon a building having a concrete deck roof.

FIG. 12C is an enlarged view of the portion of the support member secured to the weight-bearing beam.

FIG. 13 is a perspective view of a coupling used for upper and lower coupling purposes.

FIGS. 14 and 14A are perspective views of an elevation-determining strut used in the present invention.

FIGS. 15 and 15A are views of coupling sleeve which enables a slidable interface between the I-beam support of the present assembly and the vertical member of the support platform thereof.

FIGS. 16, and 16A-16E, are views further to FIGS. 4 and 12A showing details of roof penetration and flashing strategies for various roof types.

### DETAILED DESCRIPTION OF THE INVENTION

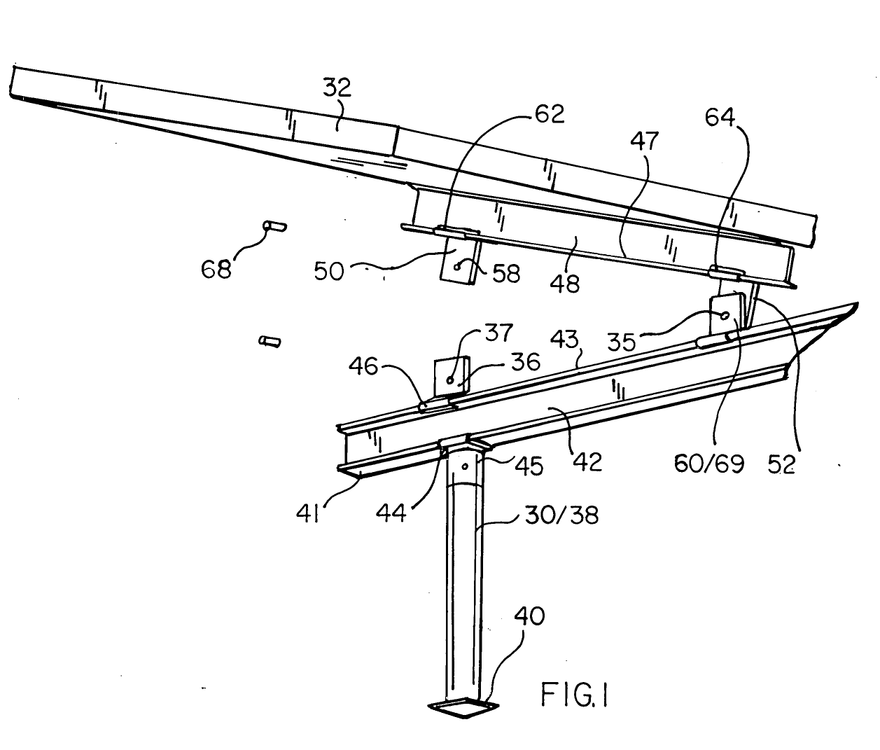

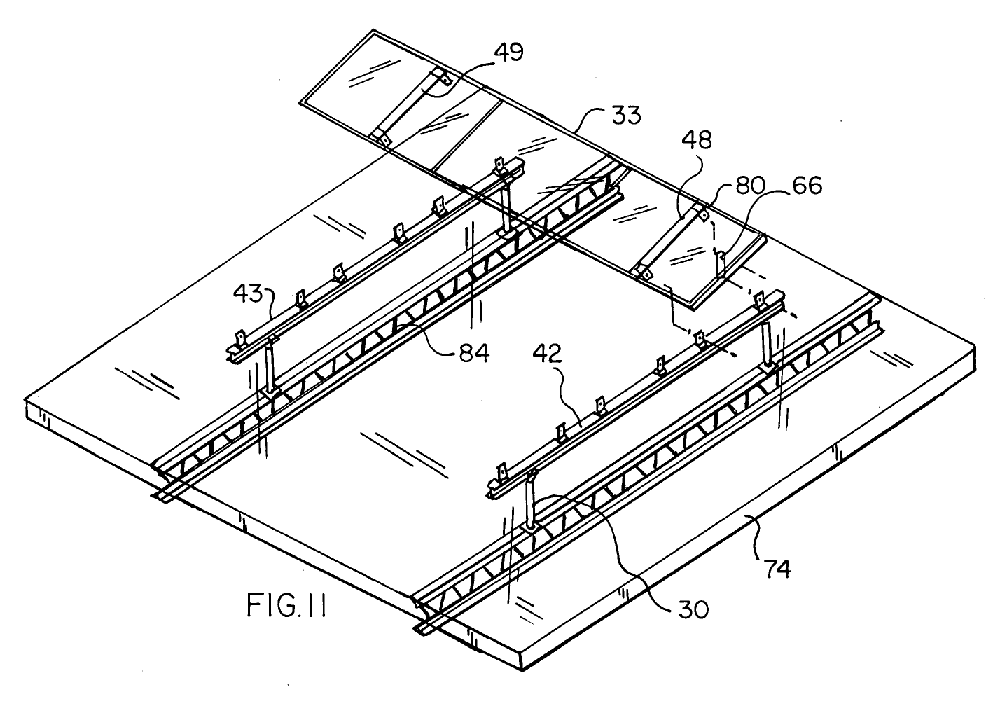

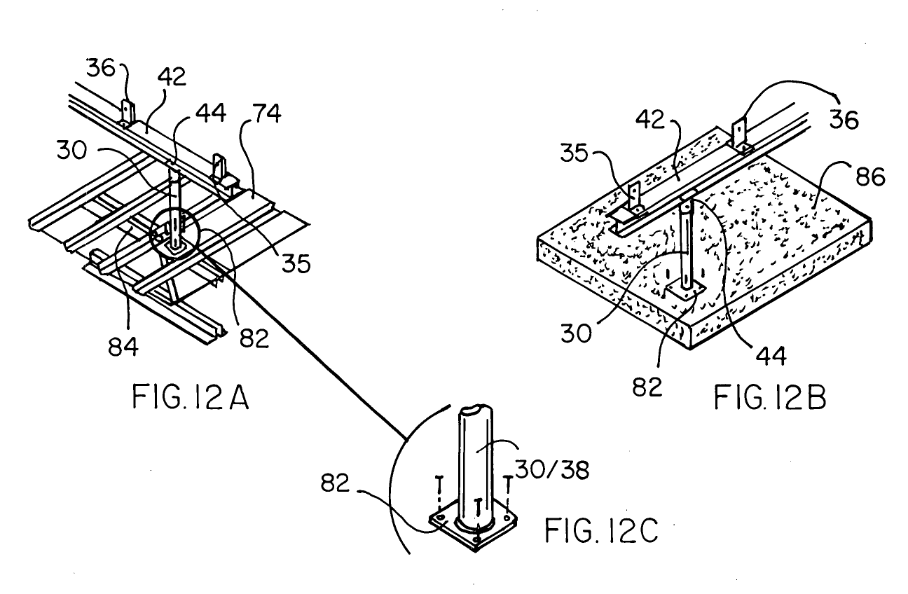

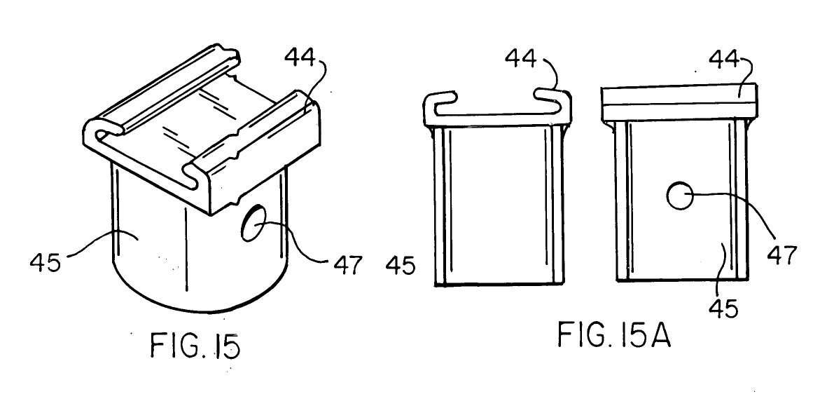

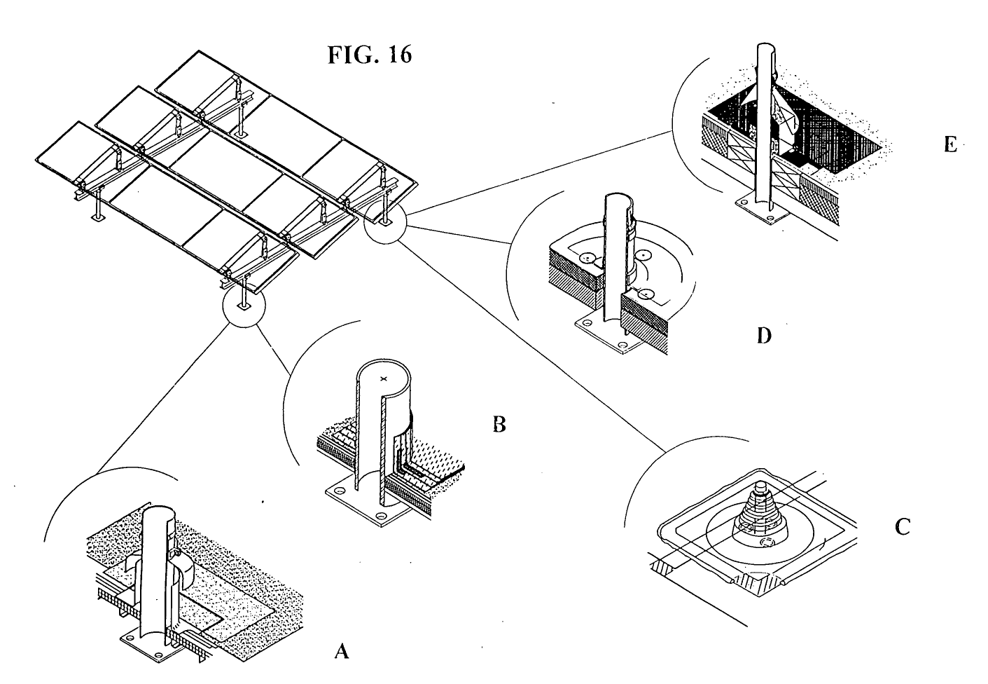

With reference to the perspective view of FIG. 1, the inventive system for the selective adjustment of the angle of elevation of groups of photo voltaic (PV) panels relative to a roof to which such panels are to be attached may be seen to include a platform 30, upon or through said roof (see FIGS. 12 and 16), of sufficient strength and stability to support one or more PV panels 32, inclusive of arrays and groups thereof. Further shown in FIG. 1 are lower couplings 46, provided upon said platform. Each of said couplings are provided with an aperture 37 within extension tabs 35 and 36 of the couplings. See also FIG. 13. As may be further noted in FIGS. 1-3, platform 30, in a preferred embodiment, includes a vertical member 38, a sleeve 45, a base 40 and an I-beam or rail 42 which is preferably secured to sleeve 45 by an integral coupling 44 which is proportioned for slidable engagement with a lower edge 41 of I-beam 42. Similarly, lower portions of said couplings 46 are proportioned for slidable engagement with an upper portion 43 of I-beam 42.

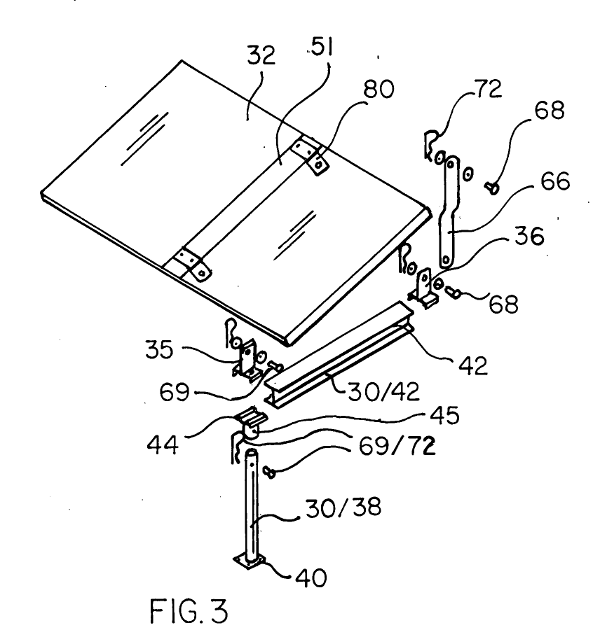

With further reference to FIGS. 1 and 3, it may be noted that upon the underside of PV panel 32, or the underside of groups thereof of panels to be suspended, are provided linear support members in the form of rails 48, each of which are provided with upper couplings 62 and 64, having respective extension tabs 50 and 52, and respective apertures 58 and 60. Upper couplings 62 are proportioned for slidable engagement with a lower edge 47 of linear member or rail 48, the combination comprising support means of the PV panels or arrays.

The structure of the above-referenced couplings 46, 62 and 64 and their extension tabs 35, 36, 50 and 52 may be more particularly seen in the isometric view of FIG. 13 as may be the elements 46/62 which permit slidable securement to the upper portion 43 of I-beam 42 and lower portion 47 of linear members 48.

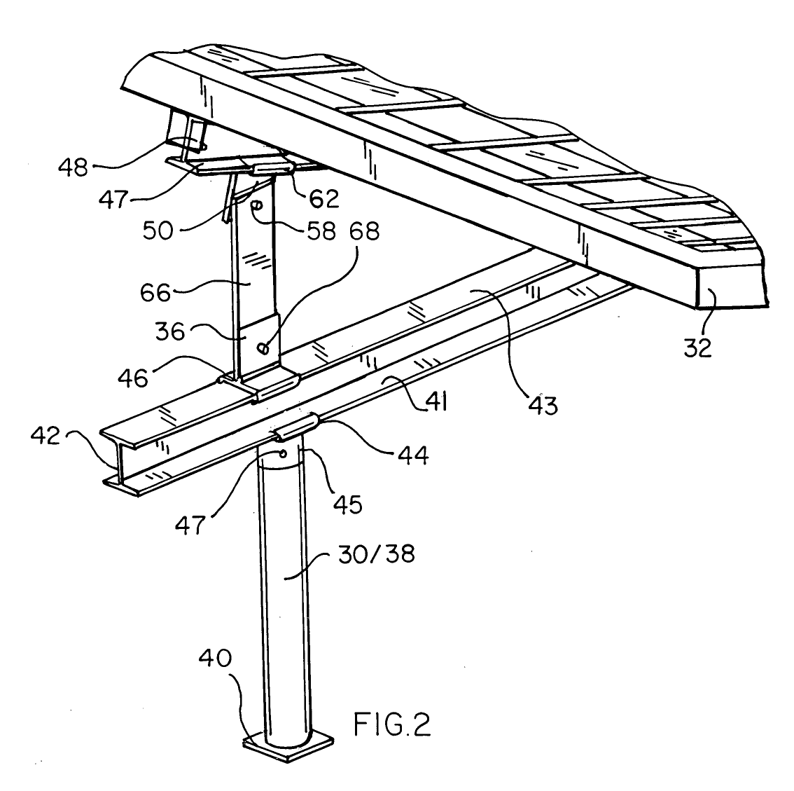

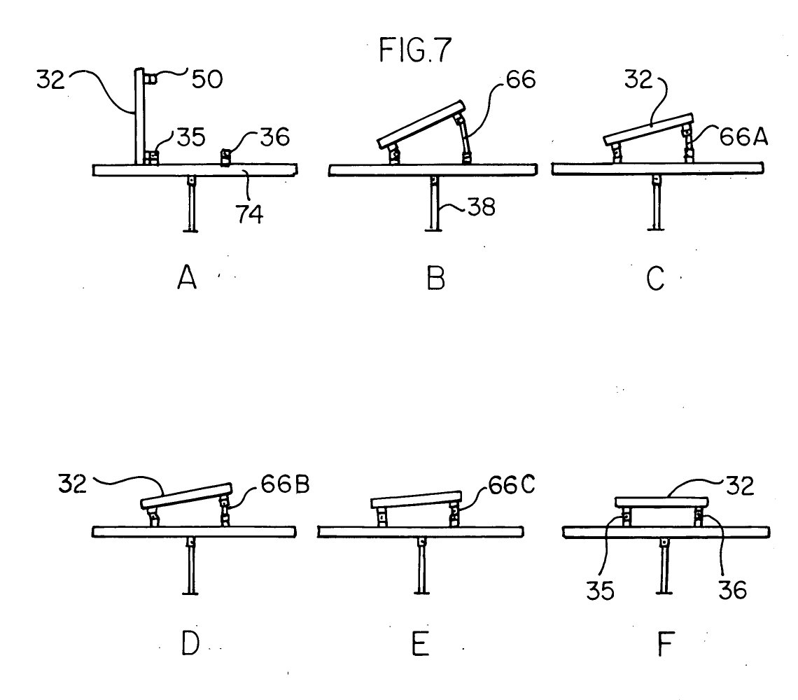

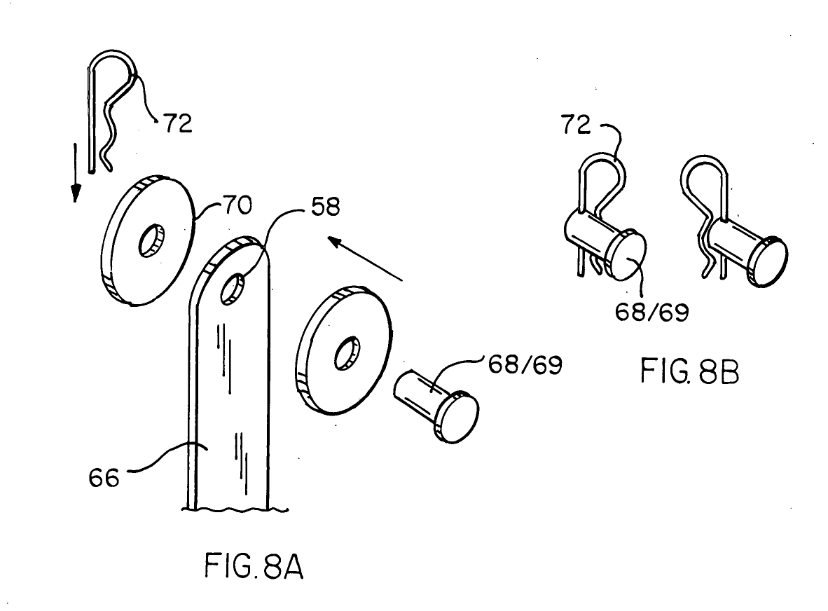

With further reference to FIG. 2, there is shown the structure of FIG. 1, however in which there has been added thereto a strut 66 which is of a selectable length intended, when secured between respective upper and lower couplings 46 and 42, to provide an intended angle of elevation of PV panels or modules thereof, relative to the plane of a roof to which a panel array is secured. Further shown in FIGS. 2 and 3 are Clevis pins 68 and 69 which are proportioned for placement through the apertures, i.e., apertures 37 and 58 (see FIG. 13) of the respective upper and lower couplings shown in FIGS. 1-4. The Clevis pins, when provided with washers 70 and hitch pins 72 (see FIGS. 8A and 8B), facilitate the ready attachment and, where desired, detachment of the strut thereby permitting selectable change of strut 66 of the system and, therewith, change of elevation of the PV panel groups 32, as is shown in FIG. 7.

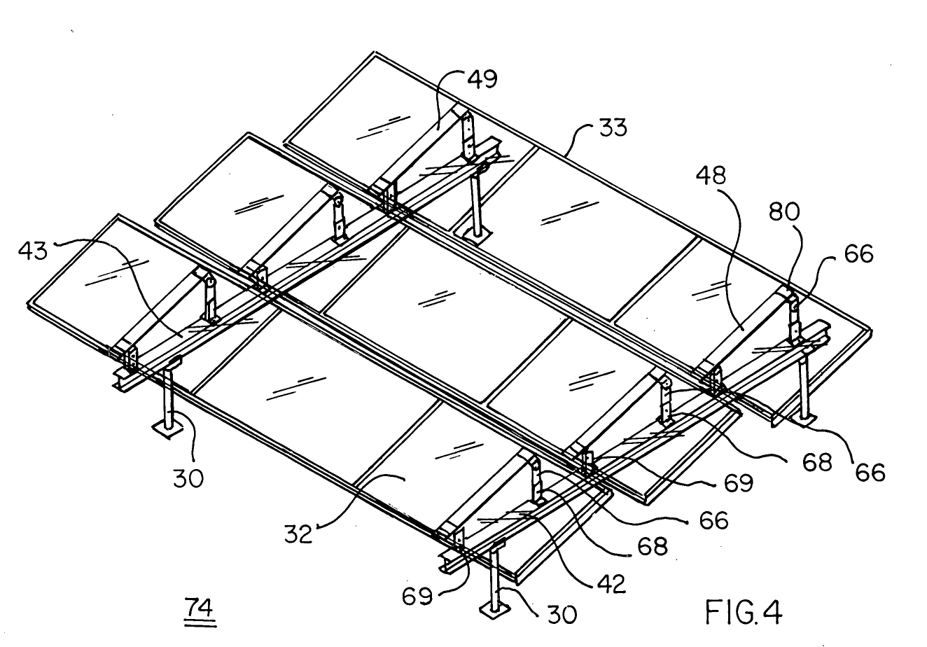

As may be further noted in FIGS. 1, 3 and 4, only alternate opposing pairs of the couplings are provided with a selectable strut 66. That is, every other coupling pair (see FIG. 4) is not provided with a selectable height strut. Thereby, alternate Clevis pins 69 serve as a point of rotation for the PV panel 32 or group 33 thereof (see FIGS. 3-4).

In FIG. 3, it may be noted that a bar 51 may be used to add structural integrity to the outer side of a panel 32.

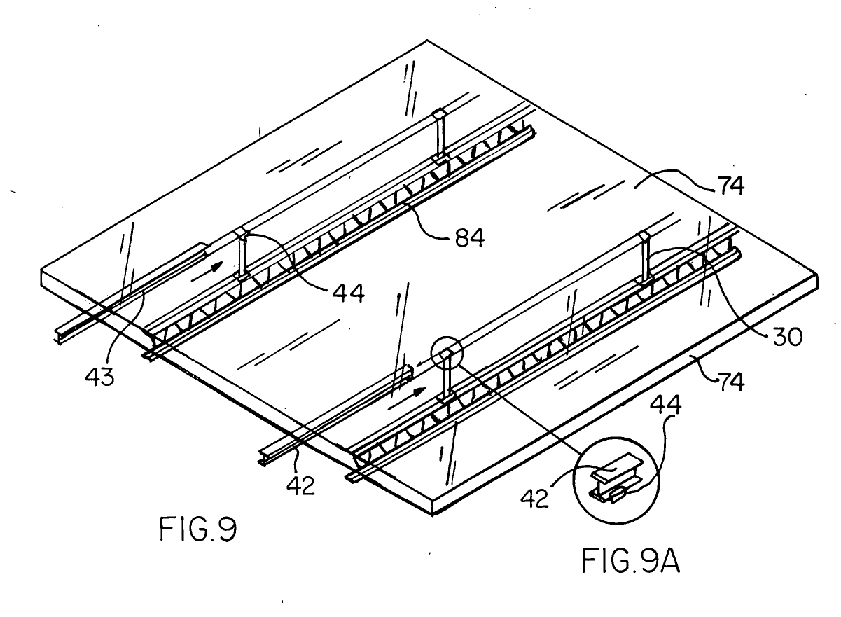

With further reference to FIGS. 4 and 9, it may be seen that said support platforms 30, including rails 42, are provided in parallel fashion upon roof 74. There is, resultantly, created a parallel series of upper and lower couplings corresponding to the planes of parallel I-beams 42 and 43. Therein exists sufficient transverse distance between each of said I-beams, and therefore each series of couplings, sufficient to accommodate a PV panel or panel array, such as group 33 (shown in FIG. 4), to be supported and selectably elevated.

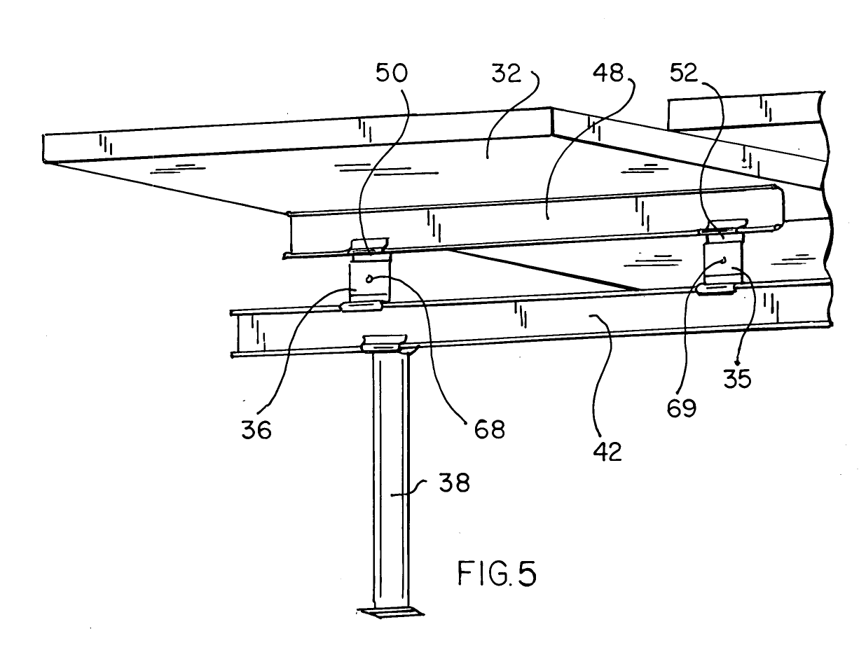

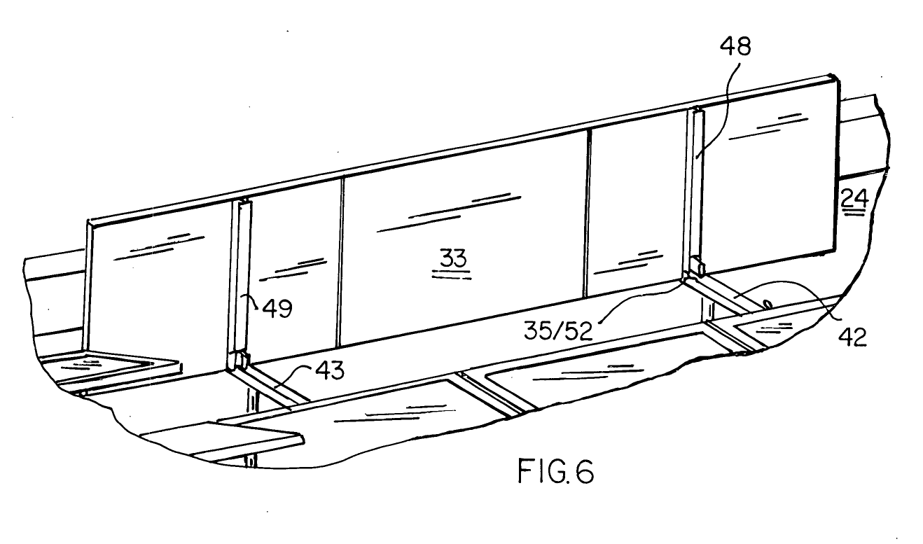

As above noted, each tab 35/36/50/52 (see FIG. 5) is provided with an aperture 37/58 which facilitates either the securement of tabs 35 and 52 to each other or tabs 36 and 50 to each other, using Clevis pins 68 or 69, respectively. Where it is desirable that the PV panels be at zero elevation relative to the roof, as is the case during a storm or storm threat, no struts are used. See FIGS. 5 and 7F. At an opposite extreme, shown in FIGS. 6 and 7A, selectable strut 36 is removed entirely such that the panel array 33 may be entirely opened to its greatest extent which is 90 degrees. This condition employed where servicing of roof 74 or the panels is necessary. The above two modes of operation, as well as all degrees of elevations therebetween, may be seen with reference to the six sub-figures A thru F of FIG. 7. Therein is shown the range of use of the present system in which, in sub-fig. A, is shown the vertical or service position above-described with reference to FIG. 6. At the opposite extreme, in sub-figures A thru F of FIG. 7, is shown, the hurricane, or totally secure, mode described with reference to FIG. 5 above. Therebetween are shown the use of four different selectable length struts 66 which may be employed to achieve intermediate elevation, that is, a 25 degree elevation as shown in sub-fig. B, a 20-degree elevation as shown in sub-fig. C (generally corresponding to the view of FIG. 4), a 15-degree elevation shown in sub-fig. D, and a 5-degree elevation shown in sub-fig. D of FIG. 7.

It is to be understood that the optimal degree of elevation for PV panel and groups thereof is not the same at all latitudes and, in fact, varies extensively as a function of a time of the year as the latitude increases. For example, the optimal elevation for purposes of receipt of maximum energy from the sun by the PV panels will change in the course of the year depending upon the latitude, for example, in New York, while the optimum elevation will be the same at all times of the year at the equator. In between these extremes, for example, Florida, perhaps two different elevations a year would be used to accomplish receipt of maximum quantities of light from the sun.

The physical steps employed in the assembly of the system in accordance with the above invention are shown in the views of FIGS. 9 thru 12. Therein, as may be noted, I-beams are 42/43 slidably provided within couplings 44 (see FIGS. 3, 9A and 15) after vertical members 30 have been secured to roof 74.

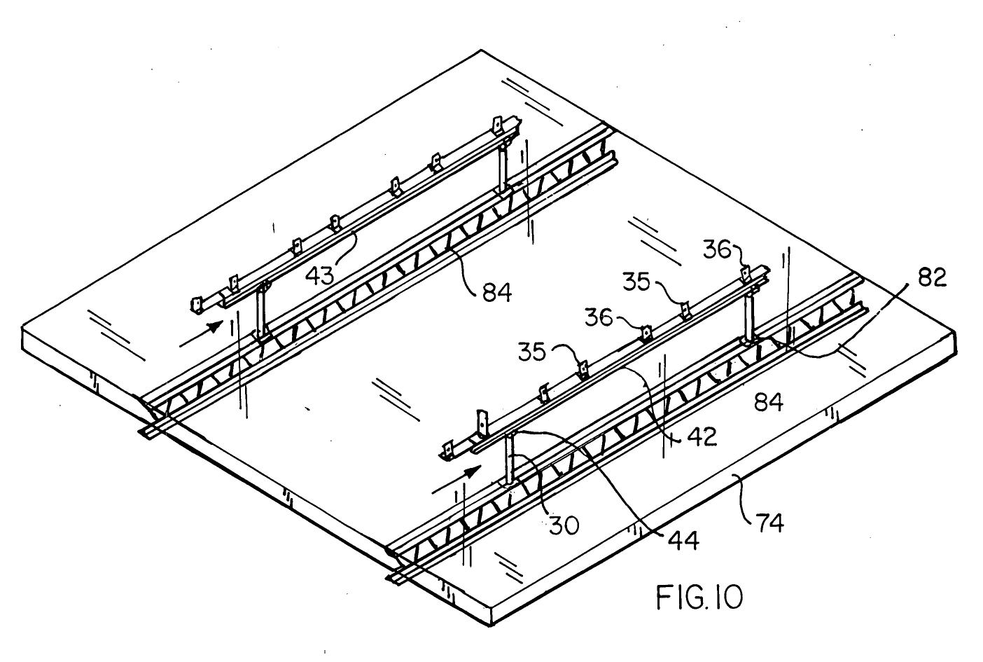

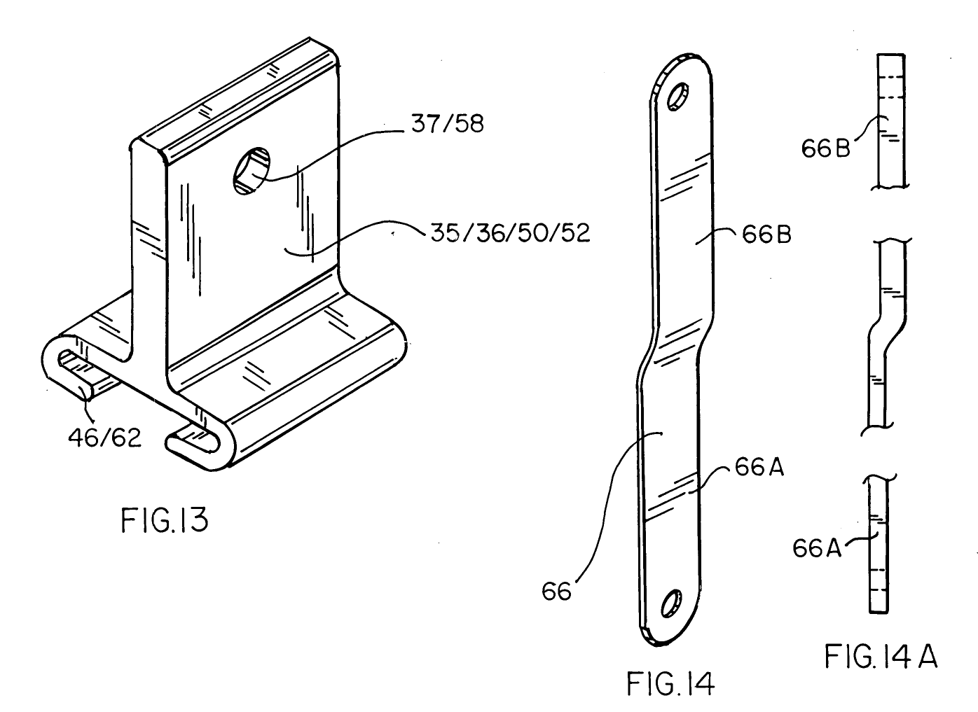

After accomplishing this step, lower couplings 35 and 36 (see FIG. 10) are slidably attached to upper portions of the respective I-beams 42/43. Thereafter (see FIG. 11), panel groups 33 are secured through the use of parallel linear support members 48 and 49 beneath the panels which, together with their corresponding brackets 80, facilitate the connection to selectable length struts 66, as above-described. In a preferred embodiment, struts 66 are provided with a unique bi-planar geometry as may be seen with reference to FIGS. 3 and 14. Therein are shown parallel surfaces 66A and 66B of each strut.

Dependent upon the nature of the roof upon which the PV panel arrays to be secured, different attachment strategies to the roof will be indicated. For example, in FIG. 4 is shown the attachment of vertical structural support 30 to an integral base 82 (see also FIGS. 12A and 12C) which in turn is secured to a bar joist 84 which is a structural member of the building. In other words, structural member 30 will penetrate roof 74 such that structural member 30 can rest directly upon a principal load bearing beam, that is, bar joist 84, of the building itself.

In FIG. 12B is shown the preferred method of attachment of the system where the roof of the building comprises a concrete deck 86. Therein vertical structural support 30 and its integral base 82 are secured directly to the concrete deck.

As above noted, FIG. 13 indicates the geometry of the coupling used in all slidable securements of the present system. Element 44 shown in FIG. 15 represents the slidable element which facilitates the positioning of I-beams 43/44 upon the structural legs 38 of the system.

FIG. 16, which is similar to FIG. 4, shows, in sub-parts A-E thereof, the various forms of roof flashings that may be used to assure the fluid integrity of the roof 74 relative to the vertical member 38 of the support means, while preserving the roofing warranty. More particularly, FIG. 16A shows the flashing strategy for modified Bitumen; FIG. 16B for Alsan liquid flashing; FIG. 16C for EPDM roofing; FIG. 16D for TPO roofing; FIG. 16E for a Pithch pocket roof section.

While there has been shown and described the preferred embodiment of the instant invention it is to be appreciated that the invention may be embodied otherwise than is herein specifically shown and described and that, within said embodiment, certain changes may be made in the form and arrangement of the parts without departing from the underlying ideas or principles of this invention as set forth in the Claims appended herewith.

1. A method for the selectable adjustment of an angle of elevation of groups of PV panels, or panel arrays relative to a roof to which said panels are attached, the method comprising the steps of:
(a) establishing a platform, upon a structural member of sufficient strength and stability to support one or more PV panels or panel array, each platform including horizontally secured rails, each member of said series secured to a respective rail of said platform;
(b) providing a parallel series of upper couplings, each member of the series provided upon said rails and having a sufficient distance therebetween sufficient to accommodate a size of a PV panel array to be supported, each of said couplings provided with an integral extension or tabs, each having an aperture within a portion thereof not in engagement with said platform;
(c) securing linear support members to undersides of said panel arrays to be selectably elevated, each of said support members vertically co-planar with said rails of said parallel series of couplings;
(d) providing struts of fixed lengths selectably provided between alternates of said couplings of each of said series of couplings in which alternate couplings are rotationally secured to said extension tabs of couplings also secured to said rails of said platform; and
(e) detachably securing strut pairs of selectable lengths, each having an aperture at each end thereof, between corresponding lower and upper couplings alternative to said rotational or pivotal couplings,
whereby selection of Step (e) of corresponding struts of like length of each strut pair of said parallel series of couplings and rails will effect an elevation of said PV panel group or array corresponding to co-equal lengths of said strut pairs.

2. The method as recited in claim 1, in which said platform establishing Step (a) comprises:
providing series of parallel rails suspended above said roof.

3. The method as recited in claim 2, further comprising the step of securing said rails to bar joists of a building beneath said roof;

4. The method as recited in claim 2, in which said concrete deck comprises said roof.

5. A system for the selectable adjustment of an angle of elevation of groups of PV panels or panel arrays, relative to a roof to which said panels are attached, the system comprising:
(a) a platform, upon or extending thru said roof, of sufficient strength and stability to support PV panels or a PV panel array, said platform including horizontally secured rails;
(b) a parallel series of lower couplings, each member of said series provided upon said rails, and having a transverse distance therebetween sufficient to accommodate a PV panel array of a weight to be supported, each of said couplings provided with integral extensions or tabs, each having an aperture within a portion thereof not in engagement with said platform;
(c) linear support members secured to undersides of said panel arrays to be selectably elevated, each of said support members substantially co-planar with said rails of said parallel series of lower couplings;
(d) struts of fixed lengths selectably provided between alternates of said lower couplings within each of said series of couplings, in which alternate couplings, not associated with said struts, are rotationally or pivotally secured by extension tabs of each coupling and selectably secured to extensions of couplings upon said linear support members of said panel arrays; and
(e) equal length strut pairs of selectable lengths, each strut having an aperture at each end thereof, detachably securable between corresponding lower and upper couplings of each of said series pairs thereof, between said rotational couplings,
whereby selection of a pair of corresponding equal length struts, related to coupling pairs upon said parallel series of couplings and rails, will effect an angle of elevation of a PV panel array as a function of the length of the co-equal lengths of said struts within the parallel series of couplings and rails.

6. The system as recited in claim 5, in which said platform comprises:
series of parallel rails suspended above said roof.

7. The system as recited in claim 6, in which said rails include means for securement to a horizontal structural beam of a building beneath said roof;

8. The system as recited in claim 6, in which a concrete deck comprises said roof.

9. The system as recited in claim 6, in which each of said rails comprises an I-beam.

10. The system as recited in claim 9, further comprising elements for slidable engagement with a bottom of each I-beam and for support thereof.

11. The system as recited in claim 5, further comprising:
a Clevis pin with a complemental hitch pin for detachable securement of selectable length links or struts, thru said apertures at said ends thereof, between said alternate lower couplings and said opposing extension tabs.

12. The system as recited in claim 5, each coupling of each parallel series of coupling proportioned for slidable engagement with a top of each I-beam.

13. The system as recited in claim 1, in which each of said extension tabs includes a coupling proportioned for slidable engagement with a lower edge of each linear panel support member.

14. The system as recited in claim 13, in which said panel support members comprise I-beams.

15. The system as recited in claim 11, said extension tabs including apertures at ends opposite to said linear support members of said PV panel groups, said apertures proportioned for receipt of said Clevis pins.

16. The system as recited in claim 12 in which, each of said extension tabs includes a coupling proportioned for slidable engagement with a lower edge of each linear panel support member.

17. The system as recited in claim 7, in which said securement comprises a vertical post having a coupling at a top end thereof in slidable engagement with a bottom surface of said rails of said platform.
